(19) United States
(12) Patent Application Publication
(10) Pub. No.: US 2015/0305155 A1
(43) Pub. Date: Oct. 22, 2015

(54) WIRING BOARD

(71) Applicant: KYOCERA Circuit Solutions, Inc., Kyoto (JP)

(72) Inventors: Makoto SHIROSHITA, Otsu-shi (JP); Hisayoshi WADA, Yasu-shi (JP)

(73) Assignee: KYOCERA Circuit Solutions, Inc., Kyoto (JP)

(21) Appl. No.: 14/690,625

(22) Filed: Apr. 20, 2015

(30) Foreign Application Priority Data
Apr. 22, 2014 (JP) 2014-087874

(51) Int. Cl. H05K 1/11; H05K 1/03; H05K 1/02

(52) U.S. Cl. CPC H05K 1/112; H05K 1/0213; H05K 1/0366; H05K 1/116; H05K 1/111; H05K 2201/029; H05K 2201/09418

(57) ABSTRACT

The wiring board according to the embodiment of the present invention includes a core substrate including a through-hole for a grounding and a through-hole for a power supply disposed adjacent to each other, and a build-up layer formed on one surface of the core substrate. The through-hole for a grounding and the through-hole for a power supply have a cross-sectional shape perpendicular to a thickness direction of the core substrate, being any one of a triangular shape, a quadrangular shape and a hexagonal shape, containing a corner portion and a side portion connecting between the corner portions. The side portions of the through-hole for a grounding and the through-hole for a power supply being mutually adjacent are disposed so as to face each other.

### BACKGROUND OF THE INVENTION

1. Technical Field

The present invention relates to a wiring board for mounting a semiconductor device.

2. Background

Conventionally, a wiring board formed by a build-up method is known as a wiring board for mounting a semiconductor element such as a semiconductor integrated circuit element. FIG. 5 is a schematic cross-sectional view showing a conventional wiring board formed by the build-up method, and FIG. 6 is a plan view schematically showing the arrangement of the through-holes taken along the I′-I′ of FIG. 5.

As shown in FIG. 5, conventional wiring board 20 has build-up insulating layers 12 and build-up wiring layers 13 alternately laminated on each of the upper and lower surfaces of core substrate 11. Core conductor layer 14 made of copper foil or a copper plating layer is deposited on the upper and lower surfaces of core substrate 11. In core substrate 11, a large number of through-holes 15 penetrating from the upper surface to the lower surface are formed. On the inner wall surface of through-hole 15, a copper plating layer functioning as part of core conductor layer 14 is deposited. The horizontal cross-sectional shape of through-hole 15 is a circular shape, and a resin is filled inside through-hole 15.

In each of build-up insulating layers 12, a plurality of via holes 16 are formed. On the surface of each build-up insulating layer 12 including via hole 16, build-up wiring layer 13 made of a copper plating layer is formed. The upper and lower build-up wiring layers 13 are connected to each other through via hole 16, and are electrically connected to through-hole 15. Part of the outermost layer of build-up wiring layers 13 on the upper surface side forms circular semiconductor element connection pads 17 to be electrically connected to electrodes T′ of semiconductor element S′. A large number of semiconductor element connection pads 17 are arranged in a grid pattern corresponding to electrodes T′ of semiconductor element S′ in semiconductor element connection pad forming area A′ being a guadrangular area corresponding to semiconductor element S′. Part of the outermost layer of build-up wiring layers 13 on the lower surface side forms circular external connection pads 18 to be electrically connected to the wiring conductor of the external electric circuit board. External connection pads 18 are arranged in a grid pattern.

Both surfaces of wiring board 20 include solder resist layers 19. Solder resist layers 19 are deposited so as to expose semiconductor element connection pads 17 and external connection pads 18. Solder bumps B′ are welded to semiconductor element connection pads 17 exposed from solder resist layers 19. Semiconductor element connection pads 17 and electrodes T′ of semiconductor element S′ are to be electrically connected via solder bumps B′. External connection pads 18 and the wiring conductor of the external electric circuit board (not shown) are to be electrically connected via the solder balls.

By the way, there are increasing cases where semiconductor elements S′ adopt the terminal arrangement which includes a large number of electrodes T′ for a grounding and for a power supply in the central portion of the lower surface, and a large number of electrodes T′ for a signal in the outer peripheral portion of the lower surface so as to ensure the sufficient power supply from wiring board 20 (for example, see Unexamined Japanese Patent Publication No. 2005-64028). When such a semiconductor element S′ is mounted, as shown in FIG. 6, through-holes 15G for a grounding and through-holes 15P for a power supply are disposed in an area corresponding to semiconductor element connection pad forming area A′ at a high array density. On the other hand, through-holes 15S for a signal are disposed in the outer periphery portion of core substrate 11 at a low array density. In FIG. 6, through-holes 15G for a grounding, through-holes 15P for a power supply, and through-holes 15S for a signal are respectively denoted by reference characters of G, P, and S.

Thus, through-holes 15G for a grounding and through-holes 15P for a power supply are disposed in the area corresponding to semiconductor element connection pad forming area A′ at a high array density, whereby semiconductor element connection pads 17 for a grounding and semiconductor element connection pads 17 for a power supply can be connected respectively with through-holes 15G for a grounding and through-holes 15P for a power supply at shorter distances. Furthermore, external connection pads 18 for a grounding and external connection pads 18 for a power supply have been performed to be disposed at least in the central portion of the lower surface of wiring board 20. This enables it to connect through-holes 15G for a grounding and through-holes 15P for a power supply respectively with external connection pads 18 for a grounding and external connection pads 18 for a power supply at shorter distances.

It is important to provide semiconductor element S′ with a sufficient grounding potential and power supply potential in a stable manner so as to activate semiconductor element S′ in a stable manner. For this purpose, it is necessary to reduce the loop inductance between from semiconductor element connection pads 17 for a grounding and for a power supply to external connection pads 18 for a grounding and for a power supply. Therefore, as shown in FIG. 6, through-holes 15G for a grounding and through-holes 15P for a power supply are arranged alternately in a checkered pattern. Whereby, the electromagnetic coupling is strengthened between mutually adjacent through-hole 15G for a grounding and through-hole 15P for a power supply, and the loop inductance between the two is made to be smaller.

It is effective to narrow the adjacent interval between the two so as to strengthen the electromagnetic coupling between mutually adjacent through-hole 15G for a grounding and through-hole 15P for a power supply. However, a too narrow adjacent interval between through-hole I5G for a grounding and through-hole 15P for a power supply results in a decrease in electrical insulation reliability between the two.

### SUMMARY

In the embodiment of the present invention, while the electrical insulation reliability between the through-hole for a grounding and the through-hole for a power supply are being kept, the electromagnetic coupling between the two can be strengthened and the loop inductance between the through-hole for a grounding and the through-hole for a power supply can be reduced. Therefore, it is possible to provide a wiring board capable of providing the semiconductor element with a sufficient grounding potential and power supply potential, and capable of operating the semiconductor element satisfactorily.

The wiring board according to the embodiment of the present invention includes a core substrate including a through-hole for a grounding and a through-hole for a power supply disposed adjacent to each other, and a build-up layer formed on one surface of the core substrate, including a build-up insulating layer having a via hole, and a build-up wiring layer formed on a surface of the build-up insulation layer and on an inner surface of the via hole, the build-up wiring layer electrically connected to the through-hole, and forming at least one semiconductor element connection pad on a surface of the build-up layer. The through-hole for a grounding and the through-hole for a power supply have a cross-sectional shape perpendicular to a thickness direction of the core substrate, being any one of a triangular shape, a quadrangular shape, and a hexagonal shape, containing a corner portion and a side portion connecting between the corner portions. The side portions of the through-hole for a grounding and the through-hole for a power supply being mutually adjacent are disposed so as to face each other.

According to the wiring board according to the embodiment of the present invention, the through-hole for a grounding and the through-hole for a power supply have a cross-sectional shape perpendicular to a thickness direction of the core substrate, being any one of a triangular shape, a quadrangular shape, and a hexagonal shape, containing a corner portion and a side portion connecting between the corner portions, and the side portions of the through-hole for a grounding and the through-hole for a power supply being mutually adjacent are disposed so as to face each other, and therefore, the interval between the facing side portions (adjacent interval) is nearly constant at any part. Therefore, while the electrical insulation reliability between the through-hole for a grounding and the through-hole for a power supply are being kept, the electromagnetic coupling between the two can be strengthened, and the loop inductance between the through-hole for a grounding and the through-hole for a power supply can be reduced. Therefore, it is possible to provide a wiring board capable of providing the semiconductor element with a sufficient power supply, and capable of operating the semiconductor element satisfactorily.

### BRIEF DESCRIPTION OF THE DRAWINGS

FIG. 1 is a schematic cross-sectional view showing one embodiment of a wiring board of the present invention;

FIG. 2 is a schematic plan view showing the arrangement of the through-holes in the wiring board shown in FIG. 1;

FIGS. 3A to 3C are explanatory diagrams for illustrating the adjacent interval between the through-hole for a grounding and the through-hole for a power supply;

FIGS. 4A and 4B are explanatory diagrams for illustrating other shapes of the through-hole for a grounding and the through-hole for a power supply;

FIG. 5 is a schematic cross-sectional view showing a conventional wiring board; and

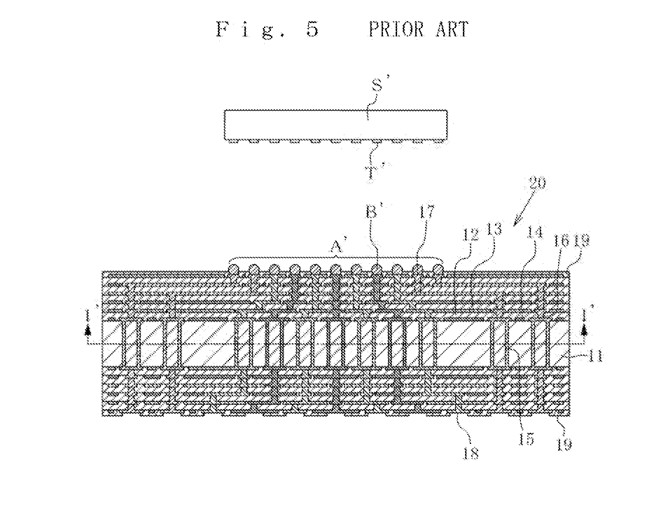

FIG. 6 is a schematic plan view showing the arrangement of the through-holes in the wiring board shown in FIG. 5.

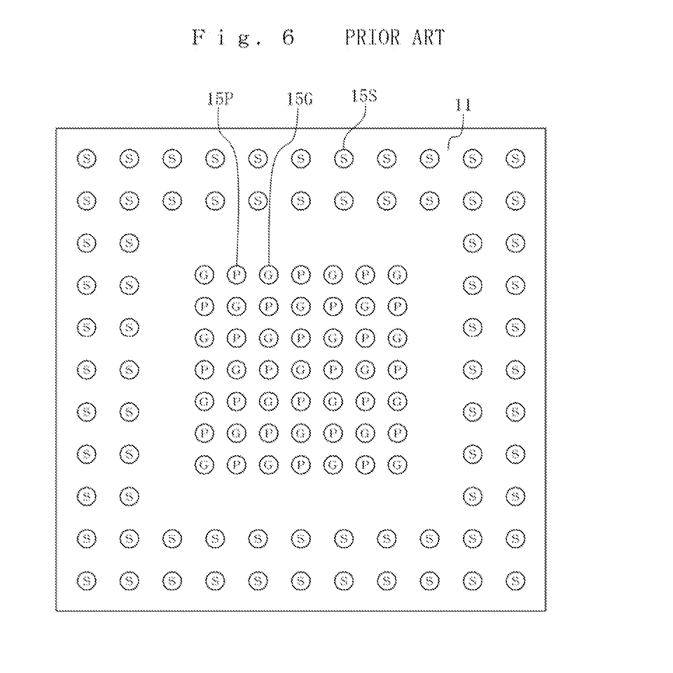

### DETAILED DESCRIPTION

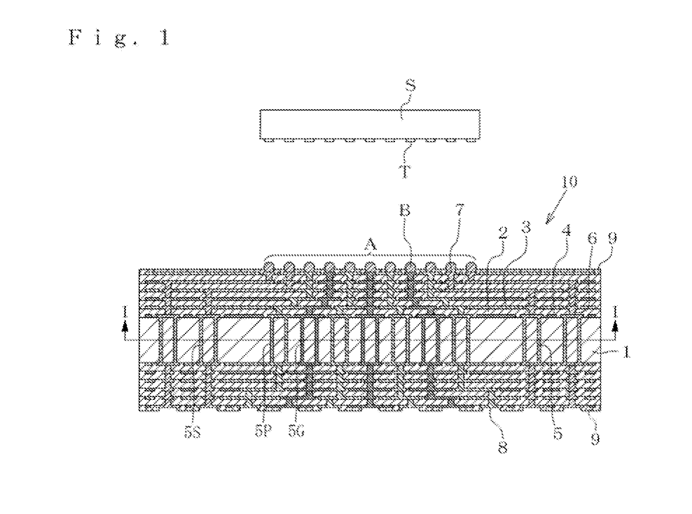

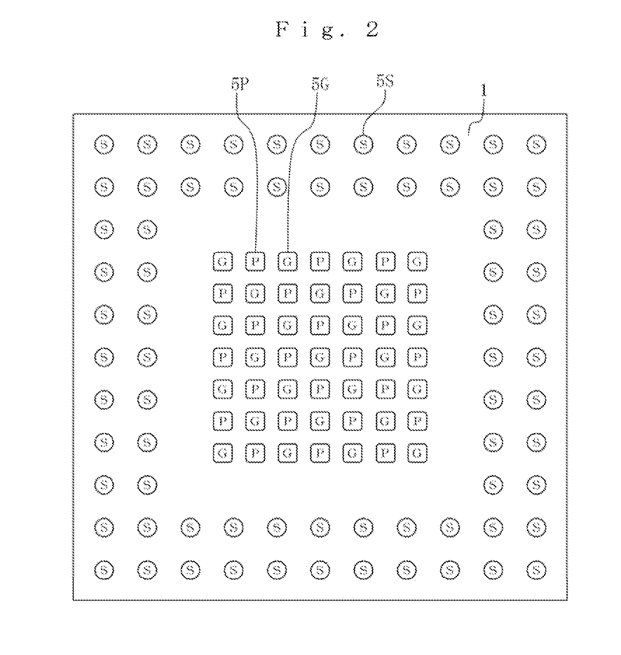

In the following, the wiring board according to the embodiment of the present invention will be described in detail with reference to FIGS. 1 and 2. FIG. 1 is a schematic cross-sectional view showing an embodiment of the wiring board according to the present invention, and FIG. 2 is a plan view schematically showing the arrangement of the through-holes taken along the line I-I of FIG. 1. As shown in FIG. 1, wiring board 10 according to the embodiment of the present invention has a structure (build-up layers) where a plurality of build-up insulating layers 2 and build-up wiring layers 3 are laminated alternately on each of the upper and lower surfaces of core substrate 1.

Core substrate 1 has a thickness of about 50 to 800 μm. Core substrate 1 is, for example, formed by an insulating board made of electrically insulating material where the glass cloth in which a glass fiber bundle is woven in the vertical and horizontal directions is impregnated with a thermosetting resin such as a bismaleimide triazine resin and an epoxy resin. On the upper and lower surfaces of core substrate 1, core conductor layers 4 made of copper foil or copper plating layers are deposited. In core substrate 1, a large number of through-holes 5 penetrating from the upper surface to the lower surface are formed. On the inner wall surface of through-hole 5, a copper plating layer functioning as part of core conductor layer 4 is deposited. Resin is filled inside through-hole 5.

Build-up insulating layer 2 has a thickness of about 20 to 50 μm, and includes an electrically insulating material where an inorganic insulating filler such as a silicon oxide is dispersed in a thermosetting resin such as an epoxy resin. In build-up insulating layer 2, a plurality of via holes 6 each of which has a diameter of about 30 to 100 μm are formed. Via hole 6 is, for example, formed by laser processing.

Build-up wiring layer 3 is formed on the surface of build-up insulating layer 2 and on the inner surface of via hole 6. Build-up wiring layer 3 is, for example, made of copper plating, and is electrically connected to through-hole 5. Furthermore, part of the outermost layer of build-up wiring layers 3 on the upper surface side of wiring board 10 forms circular semiconductor element connection pad 7. A plurality of semiconductor element connection pads 7 are arranged in a grid pattern. Semiconductor element connection pad 7 is to be electrically connected with electrode T of semiconductor element S via solder bump B.

On the other hand, part of the outermost layer of build-up wiring layers 3 on the lower surface side of wiring board 10 forms circular external connection pad 3. A plurality of external connection pads 8 are arranged in a grid pattern. External connection pad 8 is to be electrically connected with a wiring conductor of the external electric circuit board (not shown) via a solder ball.

Both surfaces of wiring board 10 include solder resist layers 9. Solder resist layers 9 are deposited so as to expose semiconductor element connection pad 7 and external connection pad 8. Furthermore, solder resist layers 9 protect the outermost layers of build-up wiring layers 3, and define the exposed portions of semiconductor element connection pads 7 and external connection pads 8.

In semiconductor element S, the terminal arrangement where a large number of electrodes T for a grounding and for a power supply are disposed in the central portion of the lower surface, and a large number of electrodes T for a signal are disposed in the outer periphery portion of the lower surface is adopted so as to secure a sufficient power supply from wiring board 10. Therefore, in wiring board 10 to mount semiconductor element S, through-holes 5G for a grounding and through-holes 5P for a power supply are disposed in the area corresponding to semiconductor element connection pad forming area A at a high array density. On the other hand, through-holes 5S for a signal are disposed in the outer periphery portion of core substrate 1 at a low array density. Through-holes 5G, 5P, and 5S are, for example, formed by blast processing.

Thus, through-holes 5G for a grounding and through-holes 5P for a power supply are disposed, whereby semiconductor element connection pads 7 for a grounding and semiconductor element connection pads 7 for a power supply can be connected respectively with through-holes 5G for a grounding and through-holes 5P for a power supply at shorter distances. Furthermore, external connection pads 8 for a grounding and external connection pads 8 for a power supply are disposed in the central portion of the lower surface of wiring board 10. This enables it to connect through-holes 5G for a grounding and through-holes 5P for a power supply respectively with external connection pads 8 for a grounding and external connection pads 8 for a power supply at shorter distances.

Here, the shapes and arrangement of through-holes 5G, 5P, and 5S in wiring board 10 according to the embodiment of the present invention are shown in FIG. 2. In FIG. 2, through-hole 5G for a grounding, through-hole 5P for a power supply, and through-hole 5S for a signal are respectively denoted by reference characters of G, P, and S.

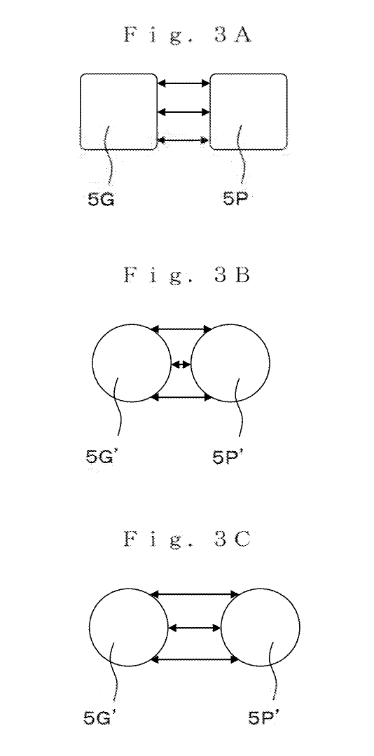

As shown in FIG. 2, in wiring board 10 according to the embodiment of the present invention, through-hole 5G for a grounding and through-hole 5P for a power supply have the horizontal cross-sectional shape, being a quadrangular shape. Specifically, the horizontal cross-sectional shape has four corner portions having rounded shape, and four side portions close to the straight lines connecting between these corner portions. The side portion is preferred to have a length of 30 to 100 μm. Through-hole 5G for a grounding and through-hole 5P for a power supply being mutually adjacent are preferred to be arranged at intervals of about 30 to 100 μm to face each other, and are arranged alternately so as to form a checkered pattern. Therefore, as shown in FIG. 3A, the interval between the facing side portions (adjacent interval) of through-hole 5G for a grounding and through-hole 5P for a power supply is nearly constant at any part.

Therefore, while keeping the electrical insulation reliability between through-hole 5G for a grounding and through-hole 5P for a power supply, it is possible to strengthen the electromagnetic coupling between the two. Whereby, the loop inductance between through-hole 5G for a grounding and through-hole 5P for a power supply can be reduced, and semiconductor element S can be provided with a sufficient power supply. As a result, wiring board 10 capable of operating semiconductor element S satisfactorily can be provided.

If through-hole 5G′ for a grounding and through-hole 5P′ for a power supply have circular shapes as shown in FIGS. 3B and 3C, the adjacent interval cannot be kept constant. As shown in FIG. 3B, if the adjacent interval between through-hole 5G′ for a grounding and through-hole 5P′ for a power supply is narrowed so that the electromagnetic coupling is strengthened, the interval at the parts where the two come closest to each other becomes too narrow. Therefore, the electrical insulation reliability between the two is Reduced.

On the other hand, in FIG. 3C, through-hole 5G′ for a grounding and through-hole 5P′ for a power supply are arranged so that the interval between the parts where the two come closest to each other is a distance not to lower the electrical insulation reliability. However, in FIG. 3C, the interval between the two becomes wider as the parts leave upwardly or downwardly from the position of the closest parts. Therefore, the electromagnetic coupling between the two is weakened.

In FIG. 2, through-hole 5S for a signal has a circular shape, and is preferred to have a diameter of 30 to 100 μm. If the electromagnetic coupling is larger between through-holes 5S for a signal, the noise is likely to occur by the electromagnetic coupling of each other. Therefore, through-hole 5S for a signal is preferred to have a circular shape. Through-holes 5S for a signal are disposed at a low array density as described above. For example, adjacent through-holes 5S for a signal are arranged at intervals of 50 to 150 μm even at the narrowest part.

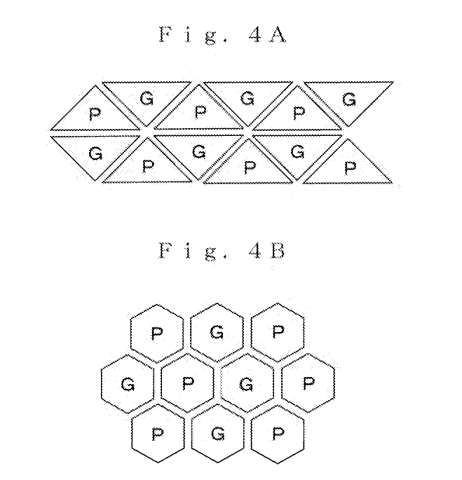

The wiring board according to the embodiment of the present invention is not intended to be limited to the embodiment described above, and various modifications are possible within the scope of the claims. For example, in wiring board 10 described above, through-hole 5G for a grounding and through-hole 5P for a power supply have rounded shapes at corner portions. However, the corner portions don't have to have rounded shapes. Although through-hole 5G for a grounding and through-hole 5P for a power supply have a square shape, the through-hole for a grounding and the through-hole for a power supply may have a quadrangular shape, a trapezoidal shape, or a parallelogram shape, and as shown in FIGS. 4A and 4B, may have a triangular shape, or a hexagonal shape. Furthermore, although the horizontal cross-sectional shape of through-hole 5S for a signal is a circular shape, this does not deny non-circular shapes. The circular shape is preferred only from the viewpoint of noise generation, and a triangular shape, a quadrangular shape, a pentagonal shape, or a hexagonal shape may be sufficient.

In addition, in wiring board 10 described above, build-up layers are formed on both sides of core substrate 1. That is, five layers of build-up insulating layers 2 and build-up wiring layers 3 are respectively laminated alternately. However, the build-up layer may be formed only on one side of core substrate 1. When the build-up layers are formed on both sides of core substrate 1, the number of laminated layers may be different in the upper and lower surfaces.

What is claimed is:

1. A wiring board comprising:
a core substrate including a through-hole for a grounding and a through-hole for a power supply disposed adjacent to each other; and
a build-up layer formed on one surface of the core substrate,
including a build-up insulating layer having a via hole, and a build-up wiring layer formed on a surface of the build-up insulation layer and on an inner surface of the via hole, the build-up wiring layer electrically connected to the through-hole, and
forming at least one semiconductor element connection pad on a surface of the build-up layer,
wherein the through-hole for a grounding and the through-hole for a power supply have a cross-sectional shape perpendicular to a thickness direction of the core substrate, being any one of a triangular shape, a quadrangular shape and a hexagonal shape, containing a corner portion and a side portion connecting between the corner portions, and
wherein the side portions of the through-hole for a grounding and the through-hole for a power supply being mutually adjacent are disposed so as to face each other.

2. The wiring board according to claim 1, wherein the through-hole for a grounding and the through-hole for a power supply are arranged alternately so as to be adjacent to each other and to form a checkered pattern.

3. The wiring board according to claim 1, wherein the build-up layer includes, on a surface of the build-up layer, a semiconductor element connection pad forming area where the plurality of semiconductor element connection pads are formed aligned.

4. The wiring board according to claim 3, wherein the through-hole for a grounding and the through-hole for a power supply are formed in an area corresponding to the semiconductor element connection pad forming area.

5. The wiring board according to claim 1, wherein a through-hole for a signal is further formed on the core substrate in an outer area of the semiconductor element connection pad forming area.

6. The wiring board according to claim 5, wherein the through-hole for a grounding and the through-hole for a power supply are arranged at a higher array density than the through-hole for a signal.

7. The wiring board according to claim 5, wherein the through-hole for a signal has a cross-sectional shape perpendicular to a thickness direction of the core substrate, being a circular shape.

8. The wiring board according to claim 5,
wherein another build-up layer is formed on the other surface of the core substrate,
wherein the build-up layer includes a build-up insulating layer having a via hole, and a build-up wiring layer formed on a surface of the build-up insulation layer and on an inner surface of the via hole, and,
wherein the build-up layer forms an external connection pad for a grounding and an external connection pad for a power supply on a surface of the build-up layer.

9. The wiring board according to claim 8, wherein the external connection pad for a grounding and the external connection pad for a power supply are formed in an area corresponding to an area where the through-hole for a grounding and the through-hole for a power supply are disposed.
